(19) United States
(12) Patent Application Publication
(10) Pub. No.: US 2014/0346027 A1
(43) Pub. Date: Nov. 27, 2014

(54) TOUCH PANEL

(71) Applicant: WINTEK CORPORATION, Taichung City (TW)

(72) Inventors: Cho-Yu Li, Taoyuan County (TW); Hsiu-Lin Chan, Hsinchu County (TW); Cheng-Yen Yeh, Taichung City (TW); Yu-Ting Chen, Taoyuan County (TW); Kuo-Chang Su, Taichung City (TW)

(73) Assignee: WINTEK CORPORATION, Taichung City (TW)

(21) Appl. No.: 14/283,206

(22) Filed: May 20, 2014

(30) Foreign Application Priority Data
May 21, 2013 (TW) 102117925

(51) Int. Cl. H03K 17/96

(52) U.S. Cl. CPC H03K 17/9622
USPC 200/600

(57) ABSTRACT

A touch panel, having a viewing region and a peripheral region adjacent to at least one edge of the viewing region, includes a plurality of first axis electrodes, a plurality of second axis electrodes, and a plurality of first traces. The first axis electrodes are disposed in the viewing region and extend along a first direction. The second axis electrodes are disposed in the viewing region and extend along a second direction. The first direction is not parallel to the second direction. The first traces are at least partially disposed in the viewing region. Each of the first traces is electrically connected to at least one of the first axis electrodes. The first traces extend from the viewing region to the peripheral region.

### BACKGROUND OF THE INVENTION

1. Field of the Invention

The present invention generally relates to a touch panel, and more particularly to a touch panel with traces disposed in a viewing region of the touch panel so as to reduce the area of a peripheral region.

2. Description of the Prior Art

In recent times, various technologies have been developed in the field of the touch panels. Generally, the touch panels include the resistance type, the capacitance type and the optical type touch panels. Concerning the capacitive touch panel, owing to its outstanding characteristics, such as high accuracy, multi-touch property, better endurance and high touch resolution, the capacitive touch panel has become a mainstream technology in the high, middle end consumer electronics. The capacitive touch panel uses sensing electrodes to detect capacitance variations at the corresponding touch points and uses connection lines, which are electrically connected to electrodes along different directional axes, to transmit the signals so as to complete the whole touch sensing and positioning process.

Please refer to FIG. 1. FIG. 1 is a schematic diagram showing a conventional touch panel. In a conventional touch panel 100, a sensing electrode 100S in a viewing region R1 of the touch panel 100 is electrically connected to an external device 100F, such as a control integrated circuit or a flexible circuit board, through peripheral traces 100T. In this configuration, signals may be received by the sensing electrode 100S and/or transmitted to the external device 100F. Precisely, one end of the peripheral traces 100T in the peripheral region R2 has to be connected to electrodes extending in different axis directions in the sensing electrode 100S and the other end of the peripheral traces 100T has to extend to be connected to the external device 100F. As the number of the different axis electrodes in the sensing electrodes 100S increases with the increased touch resolution, the number of the peripheral traces 100T also has to be increased. Since the line width of each of the peripheral traces 100T and the spacing between the peripheral traces 100T have to be kept within certain ranges in terms of electrical performance, the area of the peripheral region R2 is usually increased with the increased touch resolution. Currently, touch display apparatuses with narrow border designs are widely adopted by most of the touch panel manufacturers. However, it is usually hard to fabricate the above touch panel with narrow border design and the competitiveness of the above touch panel is negatively influenced.

### SUMMARY OF THE INVENTION

One object of the present invention is to provide a touch panel. Traces originally disposed in a peripheral region of a touch panel are at least partially disposed in a viewing region of the touch panel. In this way, the size of the peripheral region may be reduced and touch panels with narrow border design can be fabricated successfully.

To this end, a touch panel having a viewing region and a peripheral region adjacent to at least one edge of the viewing region is provided according to a preferred embodiment of the present invention. The touch panel includes a plurality of first axis electrodes, a plurality of second axis electrodes, and a plurality of first traces. The first axis electrodes are disposed in the viewing region and extend along a first direction. The second axis electrodes are disposed in the viewing region and extend along a second direction. The first direction is not parallel to the second direction. The first traces are at least partially disposed in the viewing region. Each of the first traces is electrically connected to at least one of the first axis electrodes. The first traces extend from the viewing region to the peripheral region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram showing a conventional touch panel.

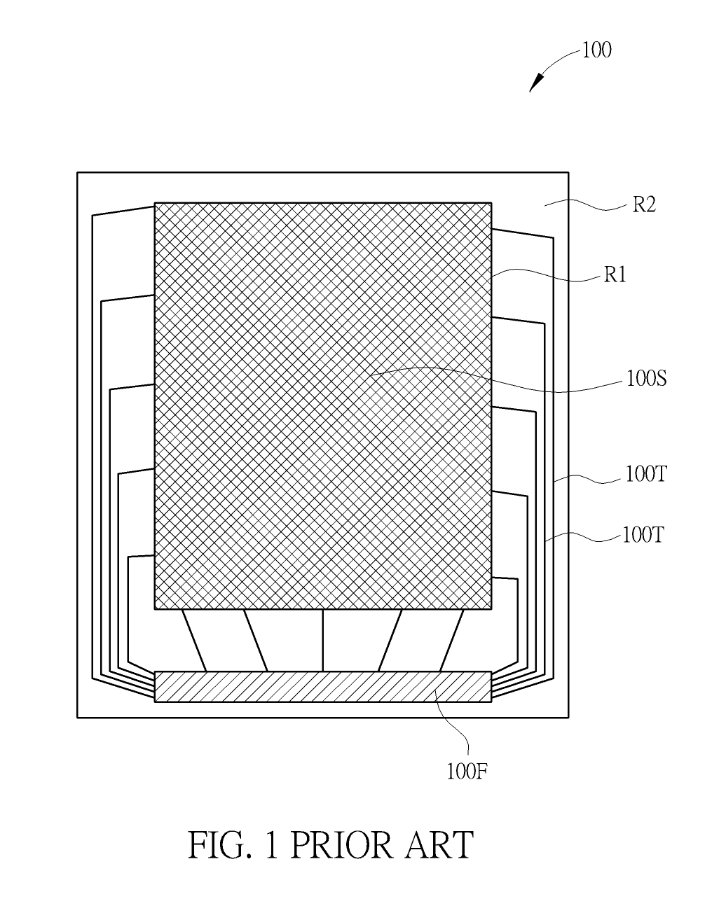

FIG. 2 is a schematic top view of a touch panel according to a first preferred embodiment of the present invention.

FIG. 3 is a partially enlarged diagram of FIG. 2.

FIG. 4 is a schematic cross-sectional diagram taken along a line A-A′ in FIG. 3.

FIG. 5 is a schematic cross-sectional diagram taken along a line B-B′ in FIG. 3.

FIG. 6 is a schematic top view of a touch panel according to a second preferred embodiment of the present invention.

FIG. 7 is a partially enlarged diagram of FIG. 6.

FIG. 8 is a schematic cross-sectional diagram taken along a line C-C′ in FIG. 7.

FIG. 9 is a schematic top view of a touch panel according to a third preferred embodiment of the present invention.

FIG. 10 is a schematic cross-sectional diagram taken along a line D-D′ in FIG. 9.

FIG. 11 is a schematic top view of a touch panel according to a fourth preferred embodiment of the present invention.

FIG. 12 is a schematic cross-sectional diagram taken along a line E-E′ in FIG. 11.

FIG. 13 is a schematic top view of a touch panel according to a fifth preferred embodiment of the present invention.

FIG. 14 is a schematic top view of a touch panel according to a sixth preferred embodiment of the present invention.

FIG. 15 is a schematic top view of a touch panel according to a seventh preferred embodiment of the present invention.

FIG. 16 is a schematic cross-sectional diagram taken along a line F-F′ in FIG. 15.

FIG. 17 is a schematic top view of a touch panel according to an eighth preferred embodiment of the present invention.

FIG. 18 is a schematic top view of a touch panel according to a ninth preferred embodiment of the present invention.

FIG. 19 is a schematic cross-sectional diagram taken along a line G-G′ in FIG. 18.

FIG. 20 is a schematic top view of a touch panel according to a tenth preferred embodiment of the present invention.

FIG. 21 is a schematic top view of a touch panel according to an eleventh preferred embodiment of the present invention.

### DETAILED DESCRIPTION

In the following description, numerous specific details are given to provide a thorough understanding of the invention. It will, however, be apparent to one skilled in the art that the invention may be practiced without these specific details. Furthermore, some well-known configurations and process steps are not disclosed in detail, as these should be well-known to those skilled in the art.

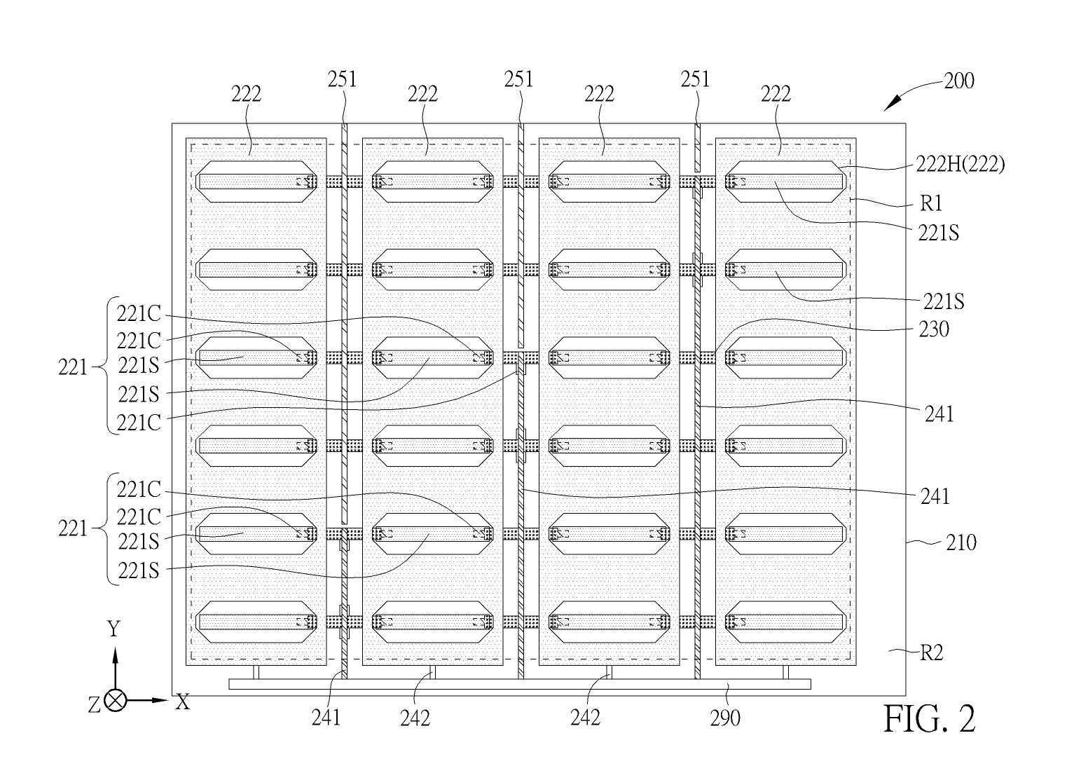

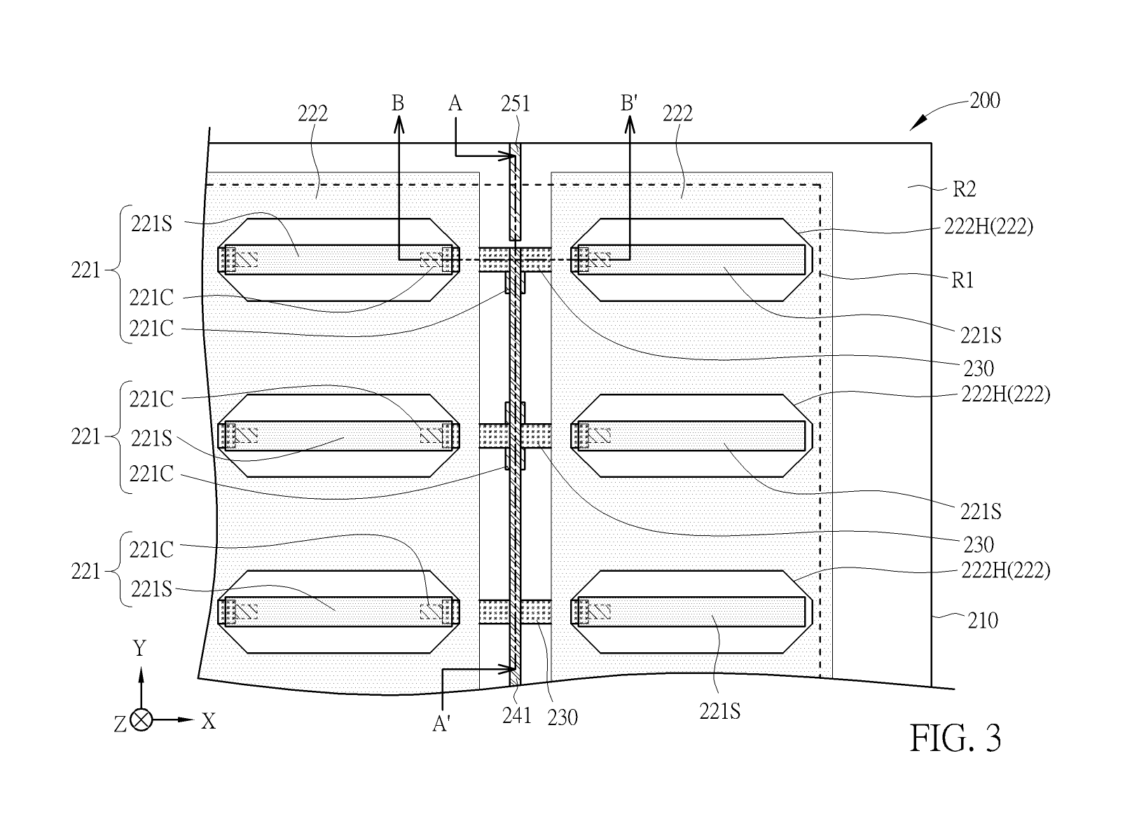

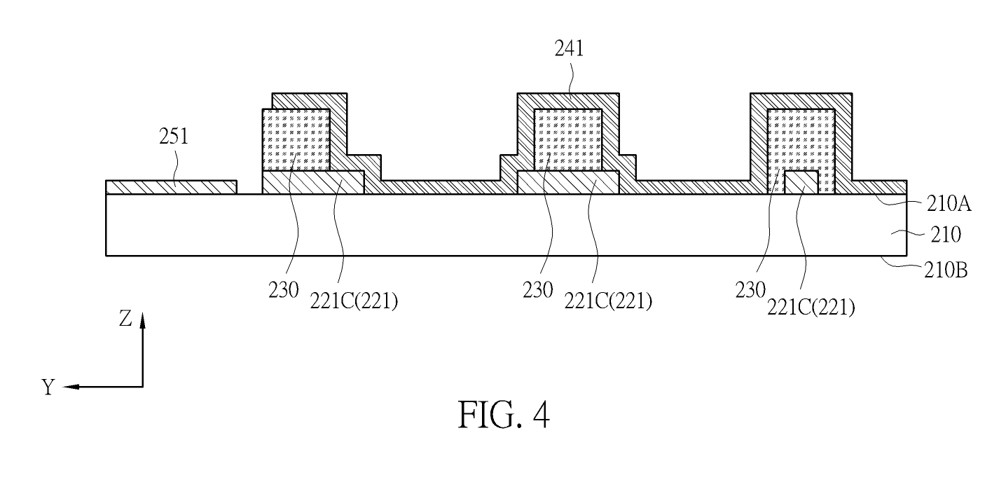

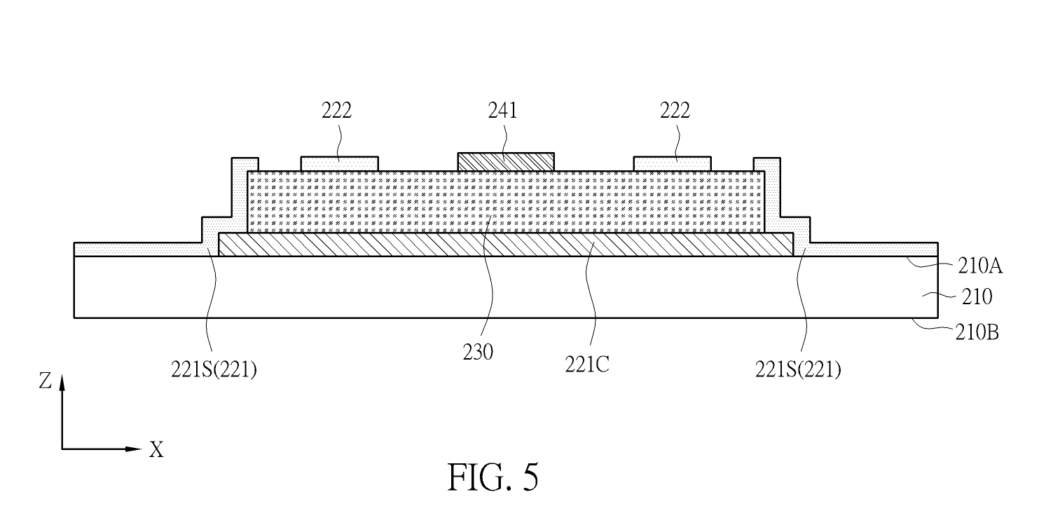

Please refer to FIG. 2 to FIG. 5. FIG. 2 is a schematic top view of a touch panel according to a first preferred embodiment of the present invention. FIG. 3 is a partially enlarged diagram of FIG. 2. FIG. 4 is a schematic cross-sectional diagram taken along a line A-A′ in FIG. 3. FIG. 5 is a schematic cross-sectional diagram taken along a line B-B′ in FIG. 3. Relative dimensions and proportions of parts of the drawings have been shown exaggerated or reduced in size for the sake of clarity and convenience. That is to say, proportions of parts in the drawings may be modified according to actual design requirements. Referring to FIG. 2 to FIG. 5, a touch panel 200 disclosed in the present embodiment includes a viewing region R1 and a peripheral region R2 adjacent to at least one edge of the viewing region R1. Generally, a decoration layer (not shown) is disposed in the peripheral region R2 of the touch panel 200 and the viewing region R1 is exposed from the decoration layer. The viewing region R1 is disposed corresponding to a display apparatus (not shown) so as to show the image from the display apparatus, but not limited thereto. Preferably, the peripheral region R2 may surround the viewing region R1 according to the present embodiment, but not limited thereto. The touch panel 200 includes a plurality of first axis electrodes 221, a plurality of second axis electrodes 222, a plurality of first traces 241, and a plurality of second traces 242. The first axis electrodes 221 are disposed in the viewing region R1 and each of the first axis electrodes 221 extends along a first direction X. The second axis electrodes 222 are disposed in the viewing region R1 and may partially extend to the peripheral region R2, but not limited thereto. The second axis electrodes 222 extend along a second direction Y. The first axis electrodes 221 are electrically isolated from the second axis electrodes 222. According to the present embodiment, the first direction X is preferably not parallel to the second direction Y, and more preferably the first direction X is substantially perpendicular to the second direction Y, but not limited thereto. The first traces 241 are at least partially disposed in the viewing region R1. It is noted that at least one of the first traces 241 are substantially disposed in the viewing region R1. In other words, the length of at least one of the first traces 241 in the viewing region R1 should exceed one centimeter. Each of the first traces 241 in the viewing region R1 is electrically connected to at least one of the first axis electrodes 221. Also, the first traces 241 may extend from the viewing region R1 to the peripheral region R2 in a direction reverse to the second direction Y, but not limited thereto. According to another embodiment of the present invention, all of the first traces 241 may extend from the viewing region R1 to the peripheral region R2 in the second direction Y. According to still another embodiment of the present invention, some of the first traces 241 may extend from the viewing region R1 to the peripheral region R2 in the second direction Y and others of the first traces 241 may extend from the viewing region R1 to the peripheral region R2 in a direction reverse to the second direction Y. The second traces 242 are disposed in the peripheral region R2 and electrically connected to the second axis electrodes 222 respectively. The first traces 241 and the second traces 242 may be used to transmit driving signals from an external device 290, such as a control integrated circuit or a flexible printed circuit board, to the first axis electrodes 221 or the second axis electrodes 222. Besides, the first traces 241 and the second traces 242 may be used to transmit touch signals received by the first axis electrodes 221 and/or the second axis electrodes 222 back to the external device 290. Accordingly, the touch positions may be determined by the external device 290 through suitable positioning calculation. In other words, the second axis electrodes 222 may serve as touch signal transmitting electrodes while the first axis electrodes 221 may serve as touch signal receiving electrodes. Therefore, the touch panel 200 may be a mutual capacitive touch panel, but not limited thereto. Because the first traces 241 are disposed in the viewing region R1 and are electrically connected to the first axis electrodes 221 in the viewing region R1, it is not necessary to connect one end of the first traces 241 to the first axis electrodes 221 in the peripheral region R2 and to connect the other end of the first traces 241 to the external device 290. In this way, the area of the peripheral region R2 on two sides of the touch panel 200 along the first direction X can be reduced and a touch panel with narrow border design may be obtained.

Furthermore, referring to FIG. 2 to FIG. 5, each of the first axis electrodes 221 disclosed in the present embodiment may include a plurality of first sub-electrodes 221S and a plurality of first connection lines 221C. The first sub-electrodes 221S are arranged along the first direction X, while the first connection lines 221C are disposed between the first sub-electrodes 221S and are used to electrically connect the first sub-electrodes 221S. In other words, each of the first axis electrodes 221 may be constructed by using first connection lines 221C to electrically connect the first sub-electrodes 221S adjacently disposed along the first direction X. Besides, each of the second axis electrodes 222 may include a plurality of hollow regions 222H arranged along the second direction Y. The first sub-electrodes 221S are disposed in the hollow regions 222H. According to the present embodiment, the first sub-electrodes 221S and the second axis electrodes 222 are preferably made of transparent conductive materials, such as indium tin oxide (ITO), indium zinc oxide (IZO), or aluminum zinc oxide (AZO), but not limited thereto. The first connection lines 221C are preferably made of metal conductive materials with relatively high conductivity, such as silver (Ag), aluminum (Al), copper (Cu), magnesium (Mg), molybdenum (Mo), titanium (Ti), chromium (Cr), a composite thereof, a stack structure thereof, or an alloy thereof, but not limited thereto. Also, the first connection lines 221C, the first sub-electrodes 221S, and the second axis electrodes 222 may be made of the same transparent conductive materials according to other preferred embodiments of the present invention. Besides, the touch panel 200 may further includes a first insulation layer 230 and a substrate 210. The substrate 210 has a first surface 210A and an opposite second surface 210B. Precisely, the first axis electrodes 221, the second axis electrodes 222, and the first traces 241 are disposed on the first surface 210A. The substrate 210 may include a rigid substrate, such as a glass substrate or a ceramic substrate, a flexible substrate, such as a plastic substrate, or the above substrate coated with an organic functional film or an inorganic functional film on its surface. In a case where the substrate 210 is a cover substrate, such as a cover glass, the second surface 210B may serve as a touch surface, but not limited thereto. The first insulation layer 230 is at least partially disposed between the first connection lines 221C and the second axis electrodes 222. The function of the first insulation layer 230 is to electrically isolate the first axis electrodes 221 from the second axis electrodes 222. The first insulation layer 230 may be made of inorganic materials, such as silicon nitride, silicon oxide, or silicon oxynitride, organic materials, such as acrylic resin, or other suitable isolation materials. The first insulation layer 230 disclosed in the present embodiment may include a plurality of island-shaped isolation bumps which are disposed at the intersections of the first axis electrodes 221 and the second axis electrodes 222, but not limited thereto. According to another preferred embodiment of the present invention, the first insulation layer may cover the entire viewing region. In this case, a plurality of contact openings may be formed in the first insulation layer so that the first connection lines 221C may be electrically connected to the first sub-electrodes 221S through the corresponding contact openings.

According to the present embodiment, each of the first traces 241 is electrically connected to at least some of the first sub-electrodes 221S through at least one first connection line 221C. For example, each of the first traces 241 may be electrically connected to several first axis electrodes 221 through the first connection lines 221C of the different first axis electrodes 221, but not limited thereto. Precisely, referring to FIG. 3 and FIG. 4, at least one of the first traces 241 intersects a plurality of first axis electrodes 221 and overlaps the first axis electrodes 221 in a vertical projection direction Z perpendicular to the substrate 210. When a predetermined first axis electrode 221 is designed to be electrically connected to the first trace 241, the dimension of the corresponding first connection line 221C in this predetermined first axis electrodes 221 may be adjusted accordingly. In this way, the first connection line 221C may be exposed from the first insulation layer 230 and be electrically connected to the first trace 241. In contrast, when another predetermined first axis electrode 221 is designed to not be electrically connected to the first trace 241, the corresponding first connection line 221C in this predetermined first axis electrode 221 may be fully covered by the first insulation layer 230 along the second direction Y. In this way, the first trace 241 may be electrically isolated from the predetermined first axis electrode 221 by the first insulation layer 230. Besides, each of the first traces 241 is disposed between two adjacent second axis electrodes 222. Each of the first traces 241 is parallel to each of the second axis electrodes 222 in the viewing region R1. In other words, each of the first traces 241 is disposed in in the spacing between the second axis electrodes 222. Accordingly, the original design of the first axis electrodes 221 and the second axis electrodes 222 has not to be changed due to these newly added first traces 241. Additionally, the touch panel 200 may further include at least one first dummy trace 251, which is disposed in the viewing region R1 and optionally extends to the peripheral region R2. The first traces 241 and the first dummy trace 251 according to the present preferred embodiment may be made of transparent conductive materials, metal conductive materials, or other suitable conductive materials. The first dummy trace 251 is disposed between two adjacent second axis electrodes 222 and is electrically isolated from the first traces 241. For different requirements, the first dummy trace 251 may be grounded or electrically floated and it may be used to prevent signal interruption. Besides, since the first dummy trace 251 may be disposed in the spacing between the adjacent second axis electrodes 222 where the first traces 241 are not existed, the negative influence on the appearance of the touch panel caused by the first traces 241 may be reduced.

In the following paragraphs, various embodiments about touch panel are disclosed and the description below is mainly focused on differences among each embodiment. In addition, like or similar features will usually be described with same reference numerals for ease of illustration and description thereof.

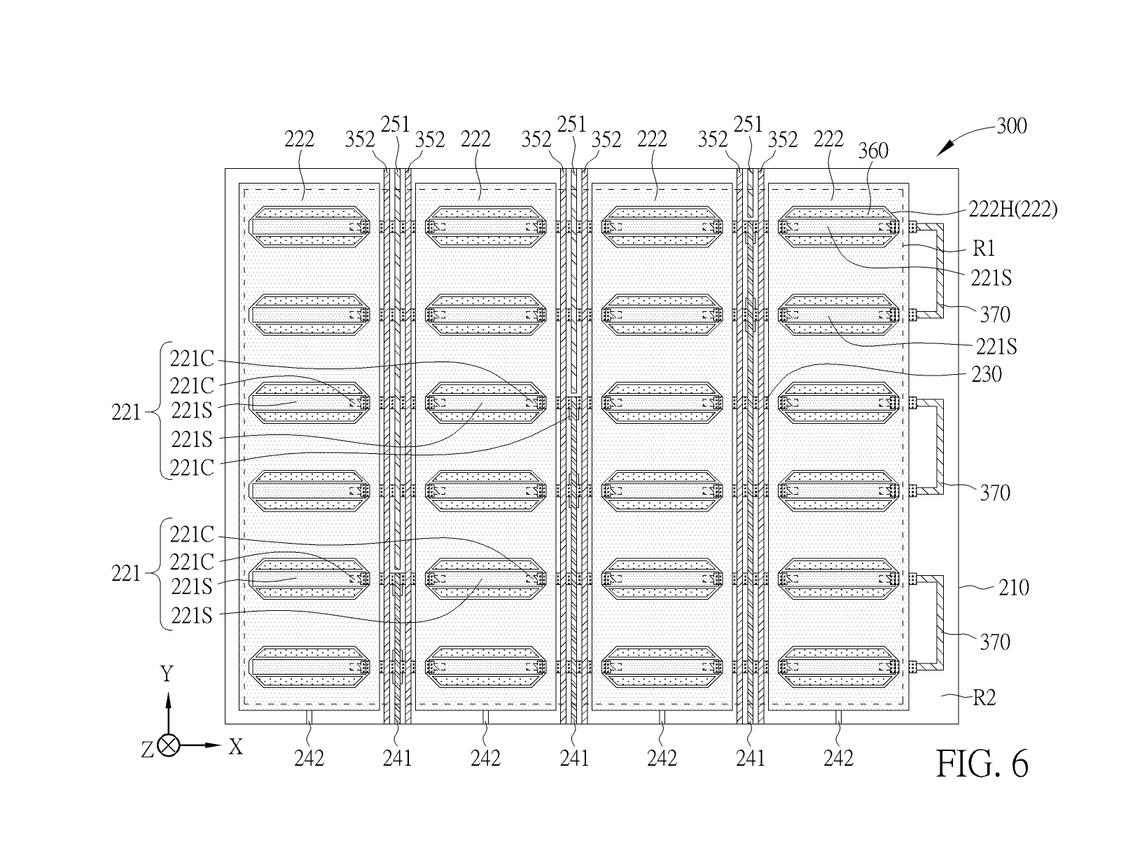

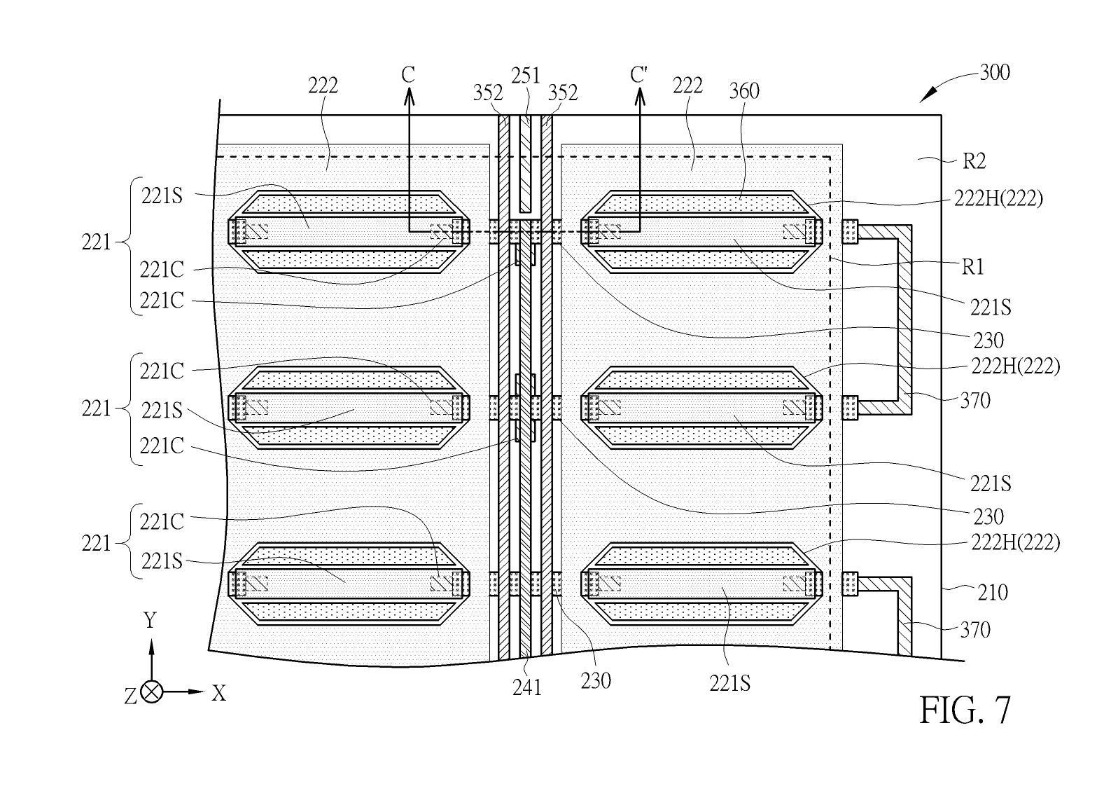

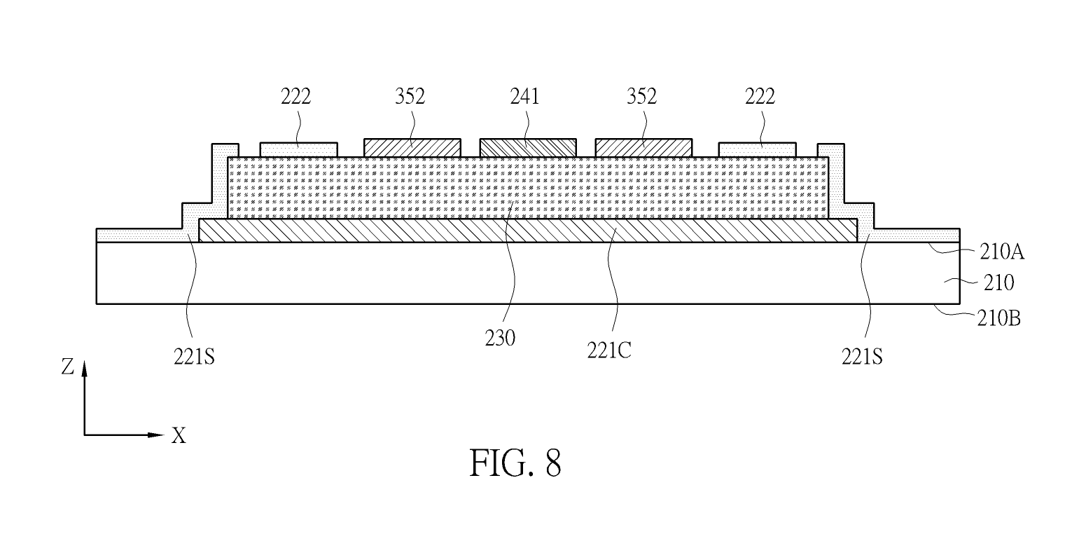

Please refer to FIG. 6 to FIG. 8. FIG. 6 is a schematic top view of a touch panel according to a second preferred embodiment of the present invention. FIG. 7 is a partially enlarged diagram of FIG. 6. FIG. 8 is a schematic cross-sectional diagram taken along a line C-C′ in FIG. 7. Referring to FIG. 6 to FIG. 8, one difference between the present embodiment and the first embodiment is that a touch panel 300 in the present embodiment further includes a plurality of second dummy traces 352, at least one dummy electrode 360, and at least one peripheral connection line 370. The second traces 352 are at least partially disposed in the viewing region R1. The second dummy traces 352 are disposed between the second axis electrodes 222 and the first traces 241. The second dummy traces 352 may be grounded or electrically floated. Two second dummy traces 352 may be disposed between every two adjacent second axis electrodes 222. Besides, each of the first traces 241 is disposed between two adjacent second dummy traces 352. In this configuration, signal interruption between the second axis electrodes 222 and the first traces 241 may be improved. The dummy electrodes 360 are disposed in the hollow regions 222H and are preferably electrically floated. The purpose of the dummy electrodes 360 is to fill the blank region in the hollow region 222H where the first sub-electrodes 221S is absent. Accordingly, the appearance of the touch panel is improved. Besides, the peripheral connection lines 370 are disposed in the peripheral region R2 and are used to electrically connect two adjacent first axis electrodes 221. In this configuration, when insufficient electrical contact occurs at the joint of the first traces 241 and one of the two adjacent first axis electrodes 221, the other first axis electrodes 221 may still be used to perform signal transmission and maintain the touch functionality. Furthermore, the resistance may also be reduced by adopting this design. Optionally, in a case where the two adjacent first axis electrodes 221 are electrically connected by the corresponding peripheral connection line 370, the first trace 241 may be connected to only one of the two adjacent first axis electrodes 221. Apart from the second dummy traces 352, the dummy electrodes 360 and the peripheral connection lines 370, the rest of the parts of the touch panel 300 disclosed in this embodiment, such as the positions of other parts, the material properties, and drive mode are almost similar to those described in the previous first preferred embodiment. For the sake of brevity, these similar configurations and properties are therefore not disclosed in detail.

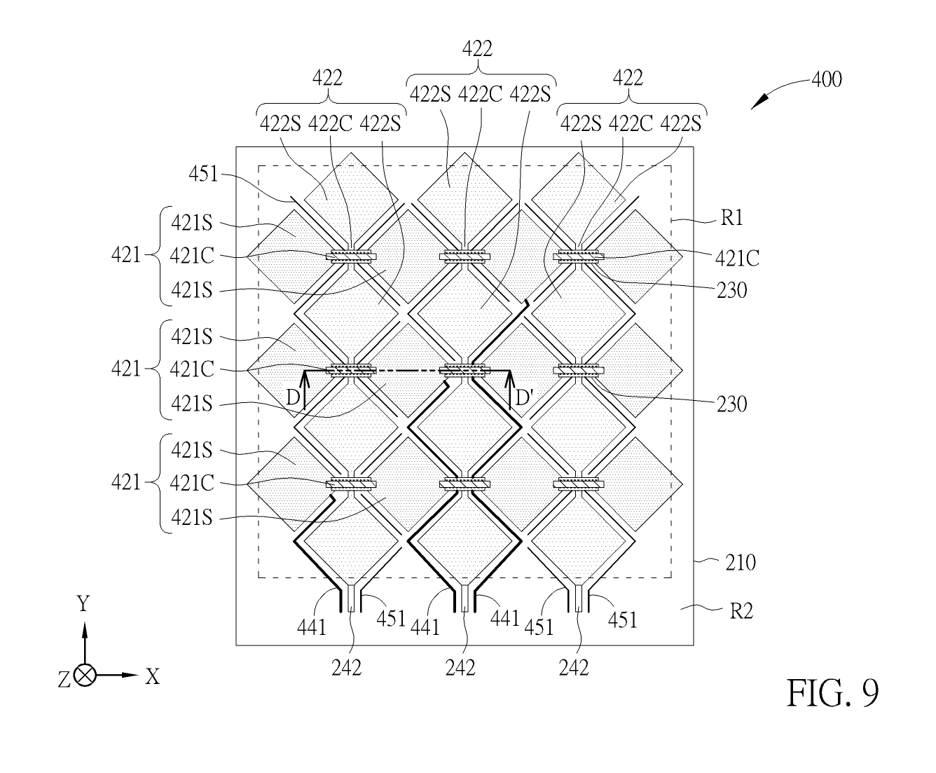

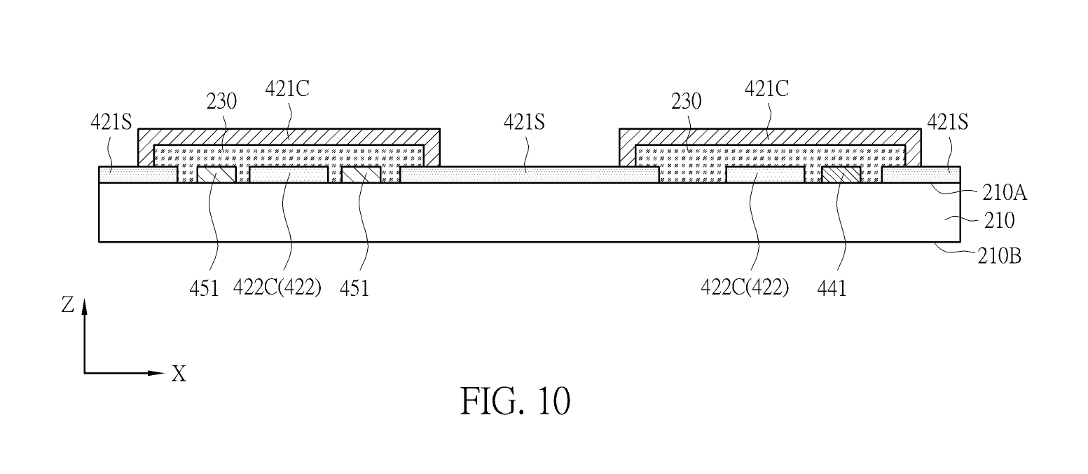

Please refer to FIG. 9 and FIG. 10. FIG. 9 is a schematic top view of a touch panel according to a third preferred embodiment of the present invention. FIG. 10 is a schematic cross-sectional diagram taken along a line D-D′ in FIG. 9. Referring to FIG. 9 and FIG. 10, a touch panel 400 disclosed in the present embodiment includes a plurality of first axis electrodes 421, a plurality of second axis electrodes 422, a plurality of first traces 441, and a plurality of second traces 242. The first axis electrodes 421 and the second axis electrodes 422 are disposed in the viewing region R1 and may partially extend to the peripheral region R2, but not limited thereto. Each of the first axis electrodes 421 extends along the first direction X, while each of the second axis electrodes 422 extends along the second direction Y. The first axis electrodes 421 are electrically isolated from the second axis electrodes 422. Each of the first axis electrodes 421 may include a plurality of first sub-electrodes 421S and a plurality of first connection lines 421C. The first sub-electrodes 421S are arranged along the first direction X, while the first connection lines 421C are disposed between the first sub-electrodes 421S and are used to electrically connect the first sub-electrodes 421S. Besides, each of the second axis electrodes 422 may include a plurality of second sub-electrodes 422S and a plurality of second connection lines 422C. The second sub-electrodes 422S are arranged along the second direction Y, while the second connection lines 422C are disposed between the second sub-electrodes 422S and are used to electrically connect the second sub-electrodes 422S. The second traces 242 are disposed in the peripheral region R2 and are electrically connected to the second axis electrodes 422 respectively. The first traces 441 are at least partially disposed in the viewing region R1. Each of the first traces 441 in the viewing region R1 is electrically connected to at least one of the first axis electrodes 421. Also, the first traces 441 may extend from the viewing region R1 to the peripheral region R2 in a direction reverse to the second direction Y, but not limited thereto.

According to the present embodiment, the first sub-electrodes 421S and the second sub-electrodes 422S are preferably diamond-shaped electrodes and disposed alternately with each other, but not limited thereto. Each of the first traces 441 is disposed between the second axis electrodes 422 and the adjacent first sub-electrodes 421S and it may be a bent line. Besides, each of the first traces 441 is disposed between two adjacent first sub-electrodes 421S and between one of the first sub-electrode 421S and the adjacent second sub-electrode 442S. Also, each of the first traces 441 may be disposed between the second axis electrodes 422 and at least one of the adjacent first sub-electrodes 421S. Additionally, the touch panel 400 may further include at least one first dummy trace 451, which is disposed in the viewing region R1 and optionally extends to the peripheral region R2. The first dummy trace 451 is disposed between the second axis electrodes 422 and at least one of the adjacent first sub-electrodes 421S and is electrically isolated from the first traces 441. For different requirements, the first dummy trace 451 may be grounded or electrically floated and it may be used to prevent signal interruption. Besides, since the first dummy trace 451 may be disposed in the spacing between the first sub-electrodes 421S and the second axis electrodes 422S where the first traces 441 are not existed, the negative influence on the appearance of the touch panel caused by the first traces 441 may be reduced. Similarly, the first dummy traces 451 may be bent lines, but not limited thereto. Apart from the shapes of the first sub-electrodes 421S, the second sub-electrodes 422S, the first traces 441, and the first dummy traces 451, the rest of the parts of the touch panel 400 disclosed in this embodiment, such as the positions of other parts, the material properties, and drive method are almost similar to those described in the previous first preferred embodiment. For the sake of brevity, these similar configurations and properties are therefore not disclosed in detail. Although the first connection lines 421C mentioned above are disposed on the first insulation layer 230, it may also be disposed under the first insulation layer 230 according to other preferred embodiments.

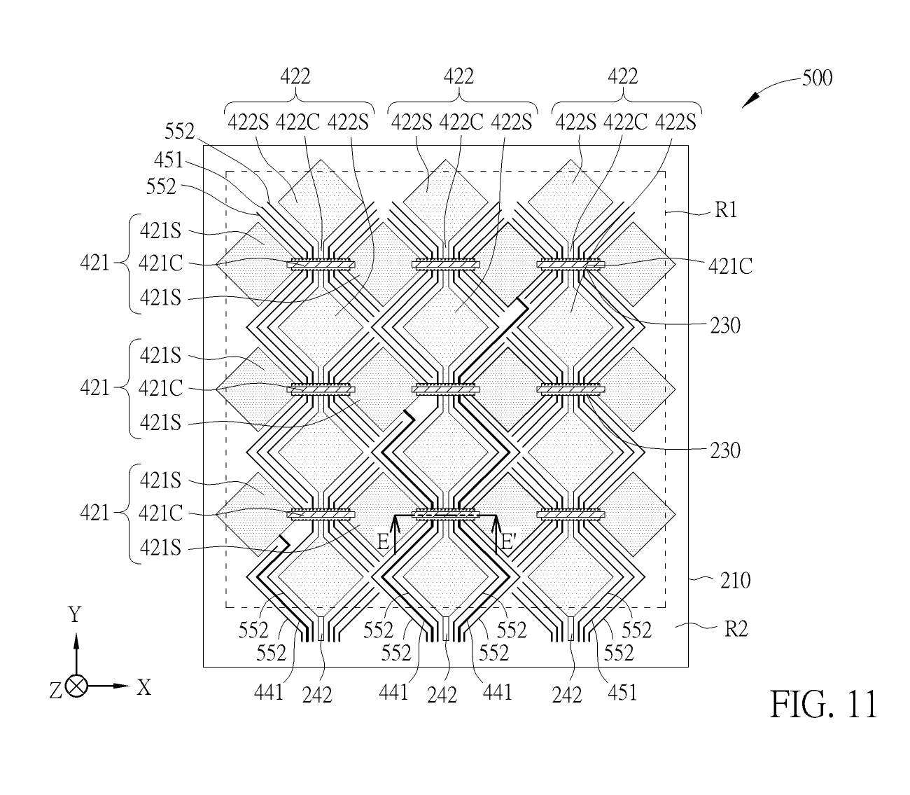

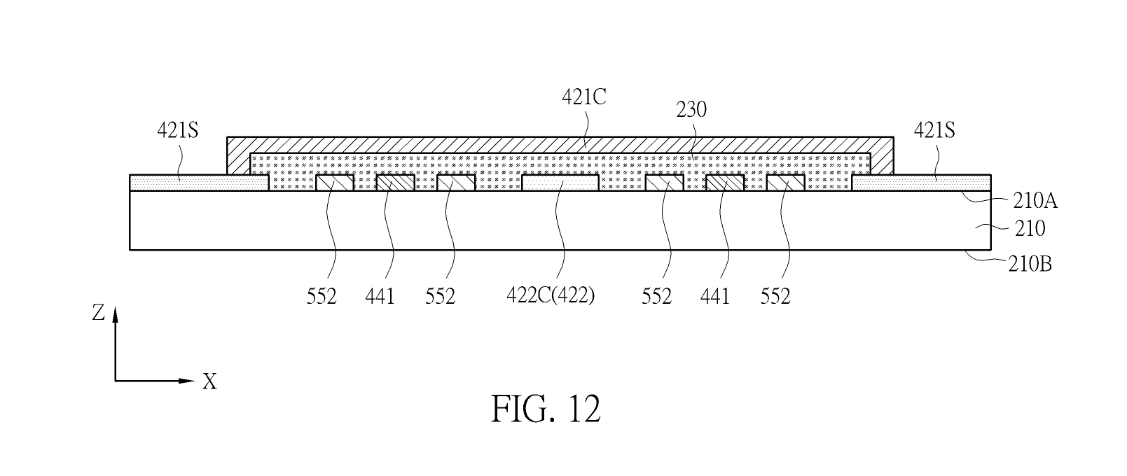

Please refer to FIG. 11 and FIG. 12. FIG. 11 is a schematic top view of a touch panel according to a fourth preferred embodiment of the present invention. FIG. 12 is a schematic cross-sectional diagram taken along a line E-E′ in FIG. 11. Referring to FIG. 11 to FIG. 12, one difference between the present embodiment and the third preferred embodiment is that a touch panel 500 in the present embodiment further includes a plurality of second dummy traces 552. The second traces 552 are at least partially disposed in the viewing region R1. The second dummy traces 552 are disposed between the second axis electrodes 422 and the first traces 441, between the first sub-electrodes 421S and the first traces 441, between the second axis electrodes 422 and the first dummy traces 451, or between the first sub-electrodes 421S and the first dummy traces 451. The second dummy traces 552 may be grounded or electrically floated. Two second dummy traces 552 may be disposed between one of the first sub-electrodes 441S and the second sub-electrode 442S disposed adjacently to the first sub-electrode 441S. Besides, each of the first traces 441 is disposed between two adjacent second dummy traces 552. In this configuration, signal interruption between the second axis electrodes 422 and the first traces 441 may be improved.

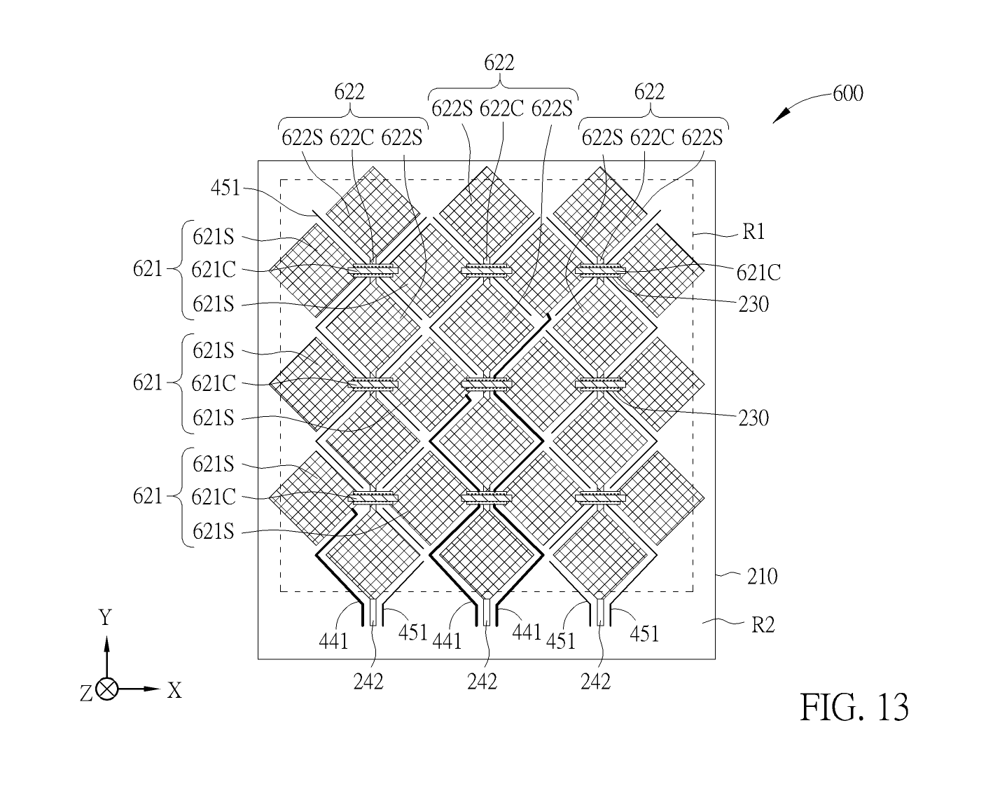

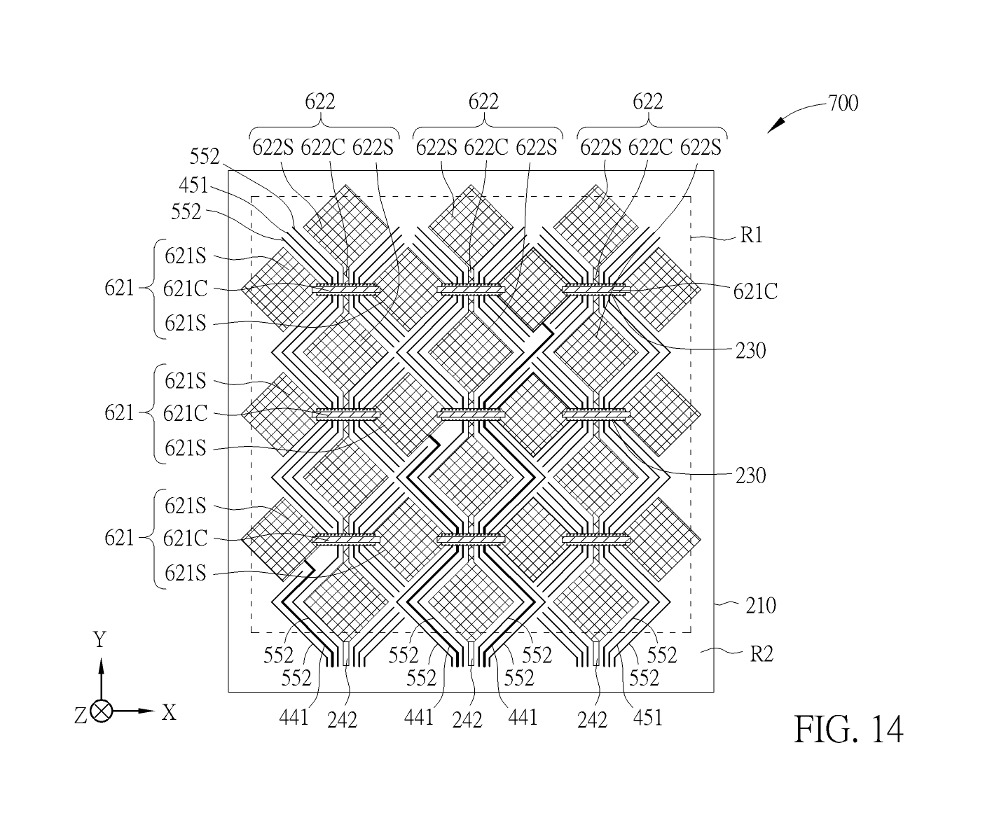

Please refer to FIG. 13 and FIG. 14. FIG. 13 is a schematic top view of a touch panel according to a fifth preferred embodiment of the present invention. FIG. 14 is a schematic top view of a touch panel according to a sixth preferred embodiment of the present invention. Referring to FIG. 13, a touch panel 600 disclosed in the present embodiment includes a plurality of first axis electrodes 621, a plurality of second axis electrodes 622, a plurality of first traces 441, and a plurality of second traces 242. The first axis electrodes 621 and the second axis electrodes 622 are disposed in the viewing region R1 and may partially extend to the peripheral region R2, but not limited thereto. Each of the first axis electrodes 621 extends along the first direction X, while each of the second axis electrodes 622 extends along the second direction Y. The first axis electrodes 621 are electrically isolated from the second axis electrodes 622. Each of the first axis electrodes 621 may include a plurality of first sub-electrodes 621S and a plurality of first connection lines 621C. The first sub-electrodes 621S are arranged along the first direction X, while the first connection lines 621C are disposed between the first sub-electrodes 621S and are used to electrically connect the first sub-electrodes 621S. Besides, each of the second axis electrodes 622 may include a plurality of second sub-electrodes 622S and a plurality of second connection lines 622C. The second sub-electrodes 622S are arranged along the second direction Y, while the second connection lines 622C are disposed between the second sub-electrodes 622S and are used to electrically connect the second sub-electrodes 622S. One difference between the touch panel 600 and the touch panel disclosed in the third embodiment is that the first axis electrodes 621 and the second axis electrodes 622 may include metal mesh. Precisely, the first sub-electrodes 621S and the second sub-electrodes 622S are preferably made of metal mesh. The first connection lines 621C and the second connection lines 622C may be made of metal mesh, transparent conductive materials, or metal lines, but not limited thereto. Furthermore, a touch panel 700 is shown in FIG. 14. One difference between the touch panel 700 and the touch panel disclosed in the fourth preferred embodiment is that at least portions of the first axis electrodes 621 and the second axis electrodes 622 are made of metal mesh.

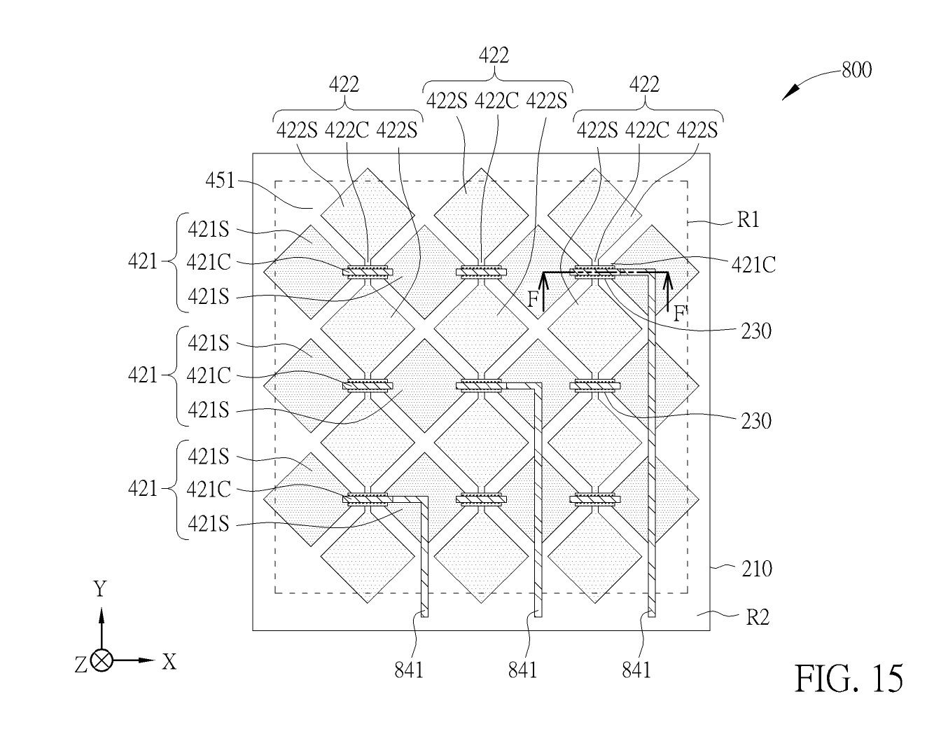

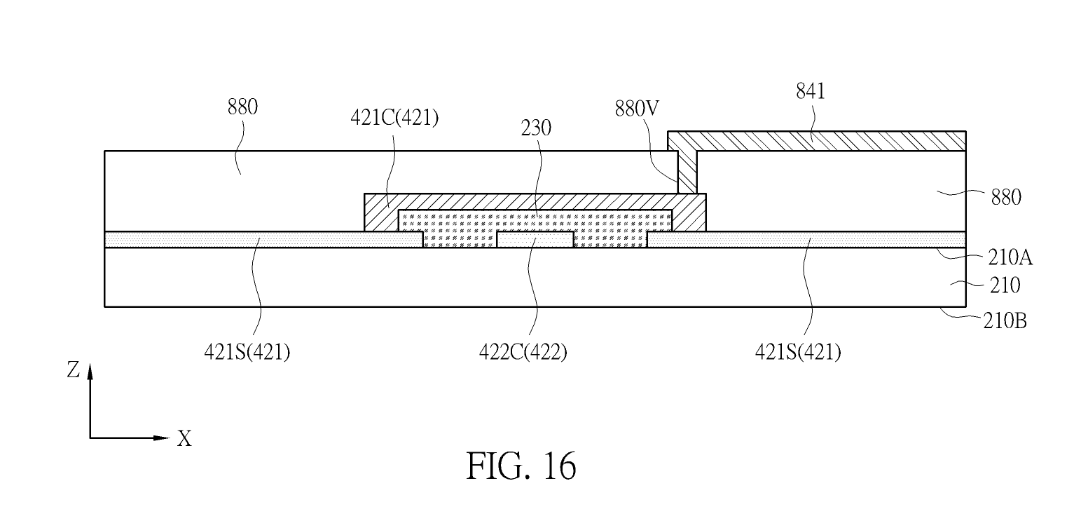

Please refer to FIG. 15 and FIG. 16. FIG. 15 is a schematic top view of a touch panel according to a seventh preferred. FIG. 16 is a schematic cross-sectional diagram taken along a line F-F′ in FIG. 15. Referring to FIG. 15 and FIG. 16, one difference between the present embodiment and the third embodiment is that a touch panel 800 disclosed in the present embodiment further includes a second insulation layer 880 and a plurality of first traces 841. The second insulation layer 880 is disposed on one side of the first surface 210A of the substrate 210 and cover the first axis electrodes 421 and the second axis electrodes 422. The first traces 841 are at least partially disposed in the viewing region R1. Each of the first traces 841 in the viewing region R1 is electrically connected to at least one of the first axis electrodes 421. Also, the first traces 841 may extend from the viewing region R1 to the peripheral region R2 in a direction reverse to the second direction Y, but not limited thereto. The second insulation layer 880 includes at least one second contact opening 880V from which at least portions of the first axis electrodes 421 are exposed. The first trace 841 is disposed on the second insulation layer 880 and is electrically connected to the corresponding first axis electrodes 421 through the second contact opening 880V. According to the present embodiment, the second contact opening 880V at least exposes portions of the first connection line 421C, and the first trace 841 is electrically connected to the first axis electrodes 421 by contacting the first connection line 421C exposed from the second contact opening 880V. Since the first traces 841 is disposed on the second insulation layer 880, the first traces 841 may not be distinguished by users from the second surface 210B. In this way, the shapes of the first traces 841 may be designed without the consideration of the positions of the first axis electrodes 421 and those of the second axis electrodes 422. Besides, the distance between the first sub-electrodes 441S and the adjacent second sub-electrodes 442S does not have to be increased due to the addition of the first traces 841. Accordingly, the ratio of the area of the first sub-electrodes 441S and the second sub-electrodes 442S to the area of the viewing region R1 may be increased and the sensing performance of the touch panel 800 is improved.

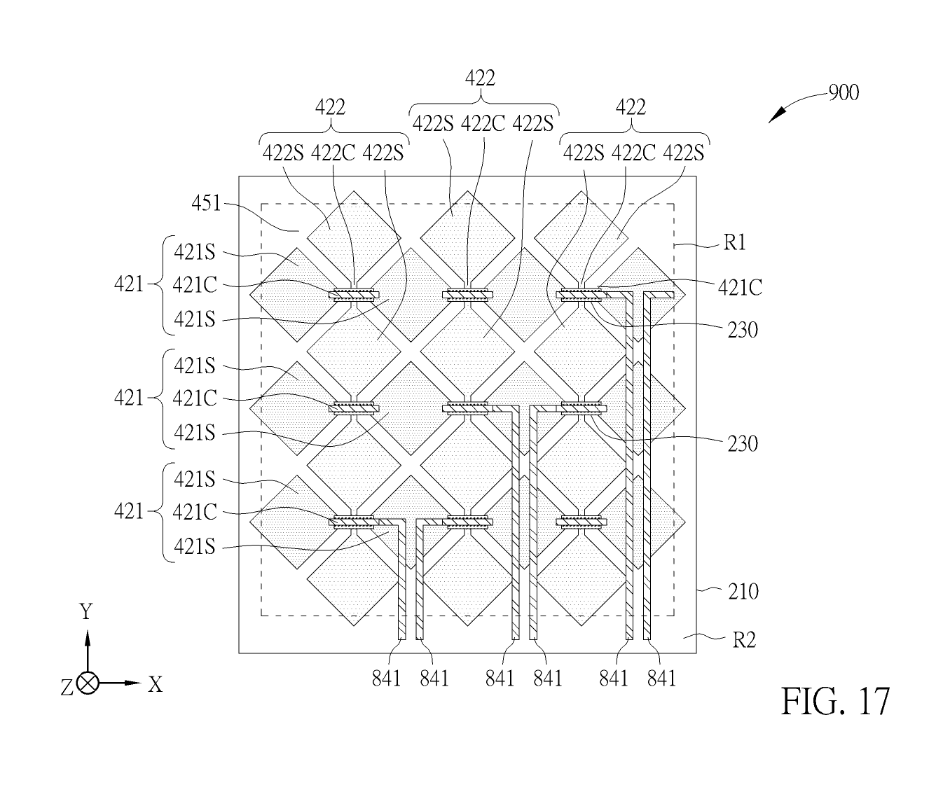

Please refer to FIG. 17. FIG. 17 is a schematic top view of a touch panel according to an eighth preferred embodiment of the present invention. Referring to FIG. 17, one difference between a touch panel 900 disclosed in the present embodiment and that disclosed in the seventh embodiment is that each of the first axis electrode 421 is electrically connected to two first traces 841 (also called double routing design). Because the touch panel 900 has a double routing design, signal delay caused by the relatively high resistance of the first axis electrodes 421 may be avoided. Besides, this double routing design may be designed together with a double bonding areas design or single bonding area design so as to further simply the structure and the drive device.

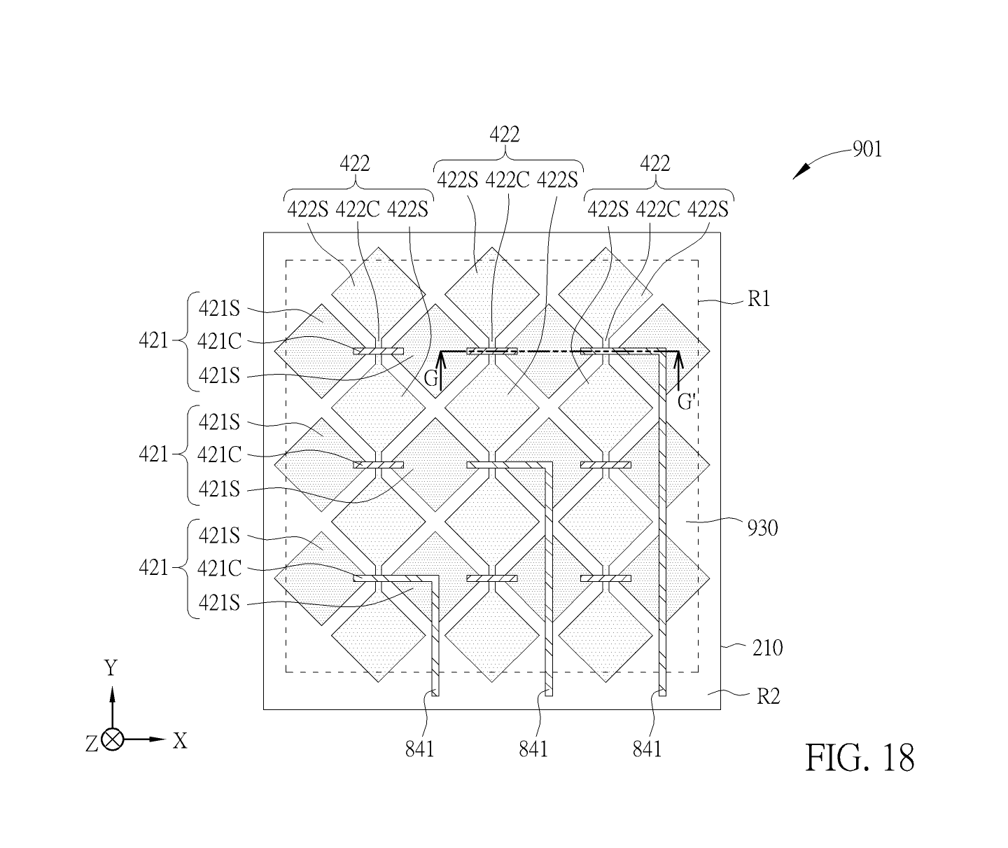

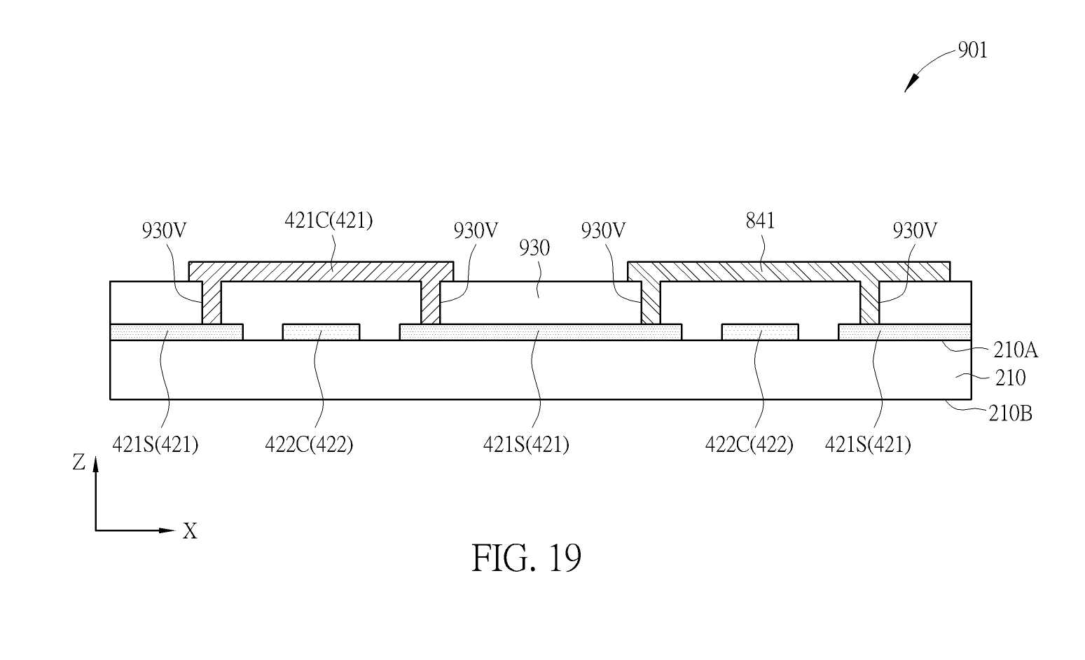

Please refer to FIG. 18 and FIG. 19. FIG. 18 is a schematic top view of a touch panel according to a ninth preferred embodiment of the present invention. FIG. 19 is a schematic cross-sectional diagram taken along a line G-G′ in FIG. 18. Referring to FIG. 18 and FIG. 19, one difference between the present embodiment and the third and eighth embodiments is that a touch panel 901 disclosed in the present embodiment further includes a first insulation layer 930 and a plurality of first traces 841. The first insulation layer 930 is partially disposed between the first connection lines 421C and the second axis electrodes 422, and the first insulation layer 930 is partially disposed between the first axis electrodes 421 and the first traces 841. Precisely, the first insulation layer 930 covers the entire viewing region R1. The first insulation layer 930 includes a plurality of first contact openings 930V from which at least portions of the first sub-electrodes 421S are exposed. The first trace 841 are disposed on the first insulation layer 930 and are electrically connected to the corresponding first sub-electrodes 421S by directly contacting the corresponding first sub-electrode 421S through the first contact openings 930V. Besides, the first connection lines 421C may be electrically connected to the adjacent first sub-electrodes 421S in the first direction X by contacting the first sub-electrodes 421S exposed from the first contact openings 930V. According to the present embodiment, the first connection lines 421C and the first traces 841 may be formed through the same fabrication process. For example, the first connection lines 421C and the first traces 841 may be formed concurrently by patterning a conductive layer so as to further simply the structure and the drive device, but not limited thereto. Since the first traces 841 are disposed on the first insulation layer 930, the first traces 841 may be less distinguished by users from the second surface 210B. In this way, the shapes of the first traces 841 may be designed without the consideration of the positions of the first axis electrodes 421 and those of the second axis electrodes 422. Besides, the distance between the first sub-electrodes 441S and the adjacent second sub-electrodes 442S is not increased due to the addition of the first traces 841. Accordingly, the ratio of the area of the first sub-electrodes 441S and the second sub-electrodes 442S to the area of the viewing region R1 may be increased and the sensing performance of the touch panel 901 is improved. It should be noted that, the first traces 841 may be disposed in regions between the first traces 841S and the second sub-electrodes 442S in a projection direction.

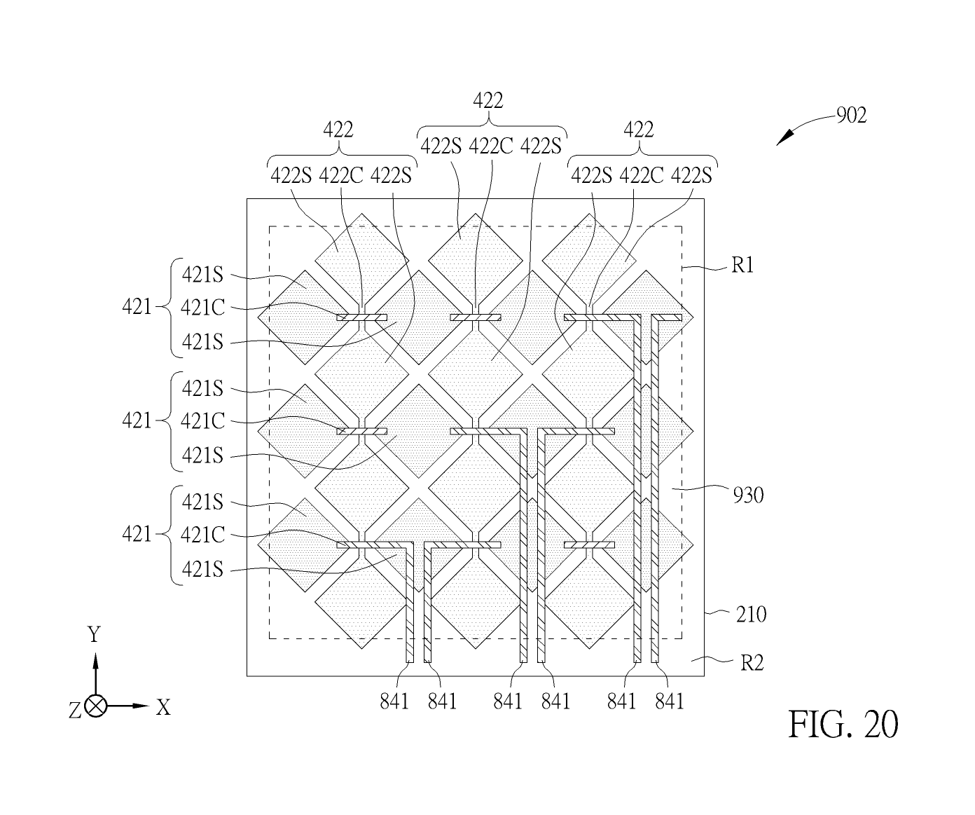

Please refer to FIG. 20. FIG. 20 is a schematic top view of a touch panel according to a tenth preferred embodiment of the present invention. Referring to FIG. 20, one difference between a touch panel 902 disclosed in the present embodiment and that disclosed in the ninth embodiment is that each of the first axis electrode 421 is electrically connected to two first traces 841 (also called double routing design). Because the touch panel 902 has a double routing design, signal delay caused by the relatively high resistance of the first axis electrodes 421 may be avoided. Besides, this double routing design may be designed together with a double bonding areas design or single bonding area design so as to further simply the structure and the drive device.

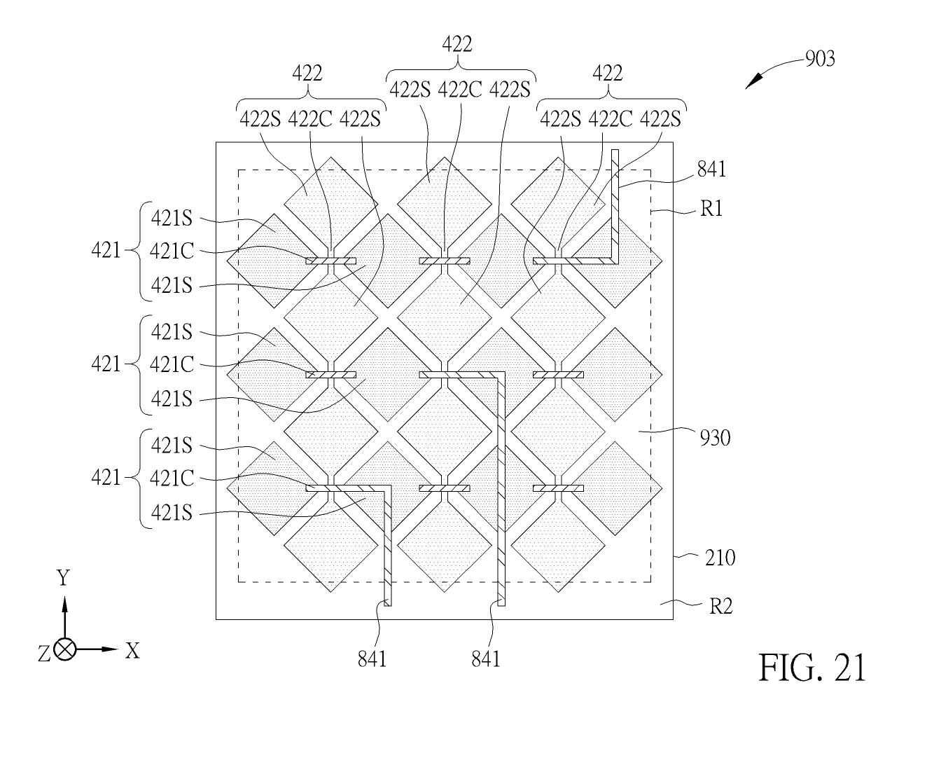

Please refer to FIG. 21. FIG. 21 is a schematic top view of a touch panel according to an eleventh preferred embodiment of the present invention. Referring to FIG. 21, one difference between a touch panel 903 disclosed in the present embodiment and that disclosed in the ninth embodiment is that at least some of the first traces 841 in the viewing region R1 extend to the peripheral region R2 in the second direction Y, and at least some of the first traces 841 in the viewing region R1 extend to the peripheral region R2 in a direction reverse to the second direction Y. In other words, the first traces 841 may extend to the peripheral region R2 in the second direction Y or in a direction reverse to the second direction Y. In this design, the lengths of some of the first traces 841 are reduced compared with those of the conventional first traces extending in the same direction. Accordingly, the degree of resistance difference among the first traces 841 is lowered. Besides, this characteristic may be applied to any of the above embodiments. That is to say, some of the first traces may extend to the peripheral region R2 in the second direction Y, while the others of the first traces may extend to the peripheral region R2 in a direction reverse to the second direction Y. Accordingly, the degree of resistance difference among the first traces is lowered.

To summarize, since the first traces electrically connected to the first axis electrodes are disposed in the viewing region of the touch panel, the area of the peripheral region as well as the border of the touch panels may be reduced. Besides, the dummy traces may be further disposed in the viewing region of the touch panels. In this way, signal interruption may be prevented and the appearance of the touch panels may be improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A touch panel, having a viewing region and a peripheral region adjacent to at least one edge of the viewing region, the touch panel comprising:
a plurality of first axis electrodes, disposed in the viewing region, wherein each of the first axis electrodes extends along a first direction;
a plurality of second axis electrodes, disposed in the viewing region, wherein each of the second axis electrodes extends along a second direction and the first direction is not parallel to the second direction; and
a plurality of first traces, at least partially disposed in the viewing region, wherein each of the first traces is electrically connected to at least one of the first axis electrodes and extends from the viewing region to the peripheral region.

2. The touch panel according to claim 1, wherein each of the first traces in the viewing region extends to the peripheral region in the second direction or in a direction reverse to the second direction.

3. The touch panel according to claim 1, wherein each of the first traces is disposed between two adjacent second axis electrodes.

4. The touch panel according to claim 1, wherein each of the first traces is electrically connected to more than one of the first axis electrodes.

5. The touch panel according to claim 1, further comprising at least one first dummy trace, at least partially disposed in the viewing region, wherein the first dummy trace is disposed between two adjacent second axis electrodes.

6. The touch panel according to claim 1, further comprising a plurality of second dummy traces, at least partially disposed in the viewing region, wherein each of the second dummy trace is disposed between one of the second axis electrodes and one of the first traces.

7. The touch panel according to claim 6, wherein each of the first traces is disposed between two adjacent second dummy traces.

8. The touch panel according to claim 1, further comprising at least one peripheral connection line, disposed in the peripheral region, wherein the peripheral connection line is electrically connected to two adjacent first axis electrodes.

9. The touch panel according to claim 1, wherein each of the first axis electrodes comprises:
a plurality of first sub-electrodes, arranged along the first direction; and
a plurality of first connection lines, disposed between the first sub-electrodes so as to electrically connect each of the first sub-electrodes.

10. The touch panel according to claim 9, wherein each of the first traces is electrically connected to at least portions of the first sub-electrodes through at least one of the first connection lines.

11. The touch panel according to claim 9, further comprising a first insulation layer, at least partially disposed between one of the first connection lines and one of the second axis electrodes.

12. The touch panel according to claim 11, wherein the first insulation layer is partially disposed between the first axis electrodes and the first traces, the first insulation layer comprises a plurality of first contact openings at least partially exposing each of the first sub-electrodes, the first traces are disposed on the first insulation layer, and the first traces are electrically connected to and in directly contact to at least portions of the first sub-electrodes through the first contact openings.

13. The touch panel according to claim 9, wherein each of the second axis electrodes comprises a plurality of hollow regions disposed along the second direction, and each of the first sub-electrodes is disposed in the hollow region.

14. The touch panel according to claim 9, wherein each of the first traces is disposed between one of the second axis electrodes and at least one of the first sub-electrodes adjacent to the second axis electrode.

15. The touch panel according to claim 1, wherein each of the second axis electrodes comprises:
a plurality of second sub-electrodes, arranged along the second direction; and
a plurality of second connection lines, disposed between the second sub-electrodes so as to electrically connect each of the second sub-electrodes.

16. The touch panel according to claim 1, further comprising a substrate, wherein the substrate has a first surface and a second surface opposite to the first surface, and the first axis electrodes, the second axis electrodes, and the first traces are disposed on the first surface.

17. The touch panel according to claim 16, further comprising a second insulation layer, disposed on a side of the first surface of the substrate and covering the first axis electrodes and the second axis electrodes, wherein the second insulation layer comprises at least one second contact opening at least partially exposing one of the first sub-electrodes, the first traces are disposed on the second insulation layer, and each of the first traces is electrically connected to the first sub-electrode through the second contact opening.

18. The touch panel according to claim 1, wherein at least one of the first axis electrodes is electrically connected to two of the first traces.

19. The touch panel according to claim 1, wherein each of the first axis electrodes and each of the second axis electrodes comprise a transparent conductive layer or metal mesh.

20. The touch panel according to claim 1, wherein at least one of the first traces extends from the viewing region to the peripheral region in the second direction, and at least one of the first traces in the viewing region extends to the peripheral region in a direction reverse to the second direction.
